(19) United States
(12) Patent Application Publication
(10) Pub. No.: US 2026/0318959 A1
(43) Pub. Date: Oct. 15, 2026

(54) VOLTAGE DETECTION CIRCUIT

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Soya TANIGUCHI, Nisshin-shi (JP); Yoshikazu FURUTA, Nisshin-shi (JP); Tomohiro NEZUKA, Nisshin-shi (JP)

(21) Appl. No.: 19/557,558

(22) Filed: Mar. 5, 2026

(30) Foreign Application Priority Data
Apr. 10, 2025 (JP) 2025-065015

(51) Int. Cl. G01R 19/10; G01R 19/25

(52) U.S. Cl. CPC G01R 19/10; G01R 19/2503

(57) ABSTRACT

A voltage detection circuit detects a differential voltage between a pair of input nodes. The circuit includes a chopper unit with a chopper switch for inverting and outputting input voltages, and an input short-circuit unit with a shorting switch for electrically shorting the input nodes. An analog-to-digital conversion unit converts the chopper output voltage to a digital signal, while a voltage detection unit determines the differential voltage based on this signal. Drive signals for the chopper and shorting switches are processed by a level conversion unit, which operates with a reference voltage generated by a reference voltage generation unit. An offset correction unit acquires an offset value in the short-circuit state and subtracts the acquired offset value from the detected value in the non-short-circuit state.

### CROSS REFERENCE TO RELATED APPLICATION

This application is based on Japanese Patent Application No. 2025-065015 filed on Apr. 10, 2025, the disclosure of which is incorporated herein by reference.

### TECHNICAL FIELD

The present disclosure relates to a volage detection circuit.

### BACKGROUND

A fully differential voltage detection circuit may employ a switch circuit known as a Capacitively-Coupled Switch (CCSW) circuit, and may detect a differential voltage between respective voltages of a pair of input nodes.

### SUMMARY

According to an aspect of the present disclosure, a voltage detection circuit detects a differential voltage between a pair of input nodes of the voltage detection circuit. The voltage detection circuit includes a chopper circuit, an input shorting circuit, an analog-to-digital conversion circuit, a detection circuit, a level conversion circuit, a reference voltage generation circuit, and an offset correction circuit. The chopper circuit has a chopper switch connected between the pair of input nodes and a pair of output nodes of the voltage detection circuit. The chopper circuit receives respective voltages at the pair of input nodes, inverts polarities of the respective voltages, and outputs the voltages with inverted polarities from the pair of output nodes. An input shorting circuit has a shorting switch connected between the pair of input nodes, and electrically shorts the pair of input nodes. The analog-to-digital conversion circuit performs analog-to-digital conversion on a voltage output from the chopper circuit. The detection circuit detects a detected value of the differential voltage based on an output signal of the analog-to-digital conversion circuit. The level conversion circuit converts a level of a first drive signal and a level of a second drive signal, and outputs the converted level of the first drive signal and the converted level of the second drive signal. The first drive signal drives the chopper switch, and the second drive signal drives the shorting switch. The reference voltage generation circuit generates a reference voltage for the level conversion circuit. The offset correction circuit may correct an offset in the detected value by performing an offset correction. The offset correction may include: acquiring, as an offset value, a first value of the differential voltage; and subtracting the offset value from a second value of the differential voltage. The first value is detected by the detection circuit when the pair of input nodes is electrically shorted by the input shorting circuit. The second value is detected by the detection circuit when the pair of input nodes is not electrically shorted by the input shorting circuit.

### BRIEF DESCRIPTION OF DRAWINGS

FIG. 1 schematically illustrates the configuration of a voltage detection circuit according to a first embodiment.

FIG. 2 schematically illustrates the signals at various units of the voltage detection circuit according to the first embodiment.

FIG. 3 illustrates an example of the configuration of a chopping unit, an input short-circuit unit, a level conversion unit, and a reference voltage generation unit according to the first embodiment.

FIG. 4 schematically illustrates an example of operational waveforms at various units of the voltage detection circuit according to the first embodiment.

FIG. 5 schematically illustrates the configuration of a voltage detection circuit according to a second embodiment.

FIG. 6 schematically illustrates an example of a correction table stored in a memory according to the second embodiment.

FIG. 7 illustrates a method for estimating the offset value under current temperature conditions according to the second embodiment.

### DETAILED DESCRIPTION

A comparative fully differential voltage detection circuit may include a selector that supplies a higher voltage at one of two input nodes as a substrate potential of a P-channel MOS transistor, and that supplies a lower voltage at another of the two input nodes as a substrate potential of an N-channel MOS transistor.

The comparative fully differential voltage detection circuit may be used for switching an input unit of an A/D converter; in such a case, it is conceivable that an external filter would be provided at the preceding stage of the voltage detection circuit. In such an assumption, the comparative fully differential voltage detection circuit results in charge flowing only from either the high potential or the low potential input, causing a voltage to be generated across resistors such as those in an external filter, and this voltage may cause an offset error. When the offset error occurs and accumulates, a decline in voltage detection accuracy may occur.

According to an aspect of the present disclosure, a voltage detection circuit detects a differential voltage between a pair of input nodes of the voltage detection circuit. The voltage detection circuit includes a chopper unit, an input shorting unit, an analog-to-digital conversion unit, a voltage detection unit, a level conversion unit, a reference voltage generation unit, and an offset correction unit. The chopper unit has a chopper switch connected between the pair of input nodes and a pair of output nodes. The chopper unit receives respective voltages at the pair of input nodes, inverts polarities of the respective voltages, and outputs the voltages with inverted polarities to the pair of output nodes. An input shorting unit has a shorting switch connected between the pair of input nodes, and electrically shorts the pair of input nodes. The analog-to-digital conversion unit performs analog-to-digital conversion on a voltage output from the chopper unit. The voltage detection unit detects a detected value of the differential voltage based on an output signal of the analog-to-digital conversion unit. The level conversion unit converts a level of a first drive signal and a level of a second drive signal, and outputs the converted level of the first drive signal and the converted level of the second drive signal. The first drive signal drives the chopper switch, and the second drive signal drives the shorting switch. The reference voltage generation unit generates a reference voltage in the level conversion unit. The offset correction unit corrects an offset in the detected value by performing an offset correction. The offset correction includes: acquiring, as an offset value, a first value of the differential voltage; and subtracting the offset value from a second value of the differential voltage. The first value is detected by the voltage detection unit when the pair of input nodes is electrically shorted by the input short-circuit unit. The second value is detected by the detection circuit when the pair of input nodes is not electrically shorted by the input short-circuit unit.

In the voltage detection circuit having the above-described configuration, since it does not include a selector as in the comparative fully differential voltage detection circuit, the offset can be suppressed to a lower level compared to the comparative fully differential voltage detection circuit. Further, according to the above configuration, when the input shorting unit and the reference voltage generation unit are not operated, the impedance of the circuit as seen from the input side becomes relatively high, resulting in a reduced amount of current flowing in. As a result, the input offset before correction can be reduced. Furthermore, according to the above configuration, during normal operation, the amount of current flowing through each of the pair of input nodes is balanced, so these currents do not become factors contributing to offset. In this regard as well, the offset can be reduced. Furthermore, according to the above configuration, offset correction is performed by the offset correction unit, allowing the offset to be further suppressed to an even lower level. Therefore, according to the above configuration, the accuracy of voltage detection can be improved.

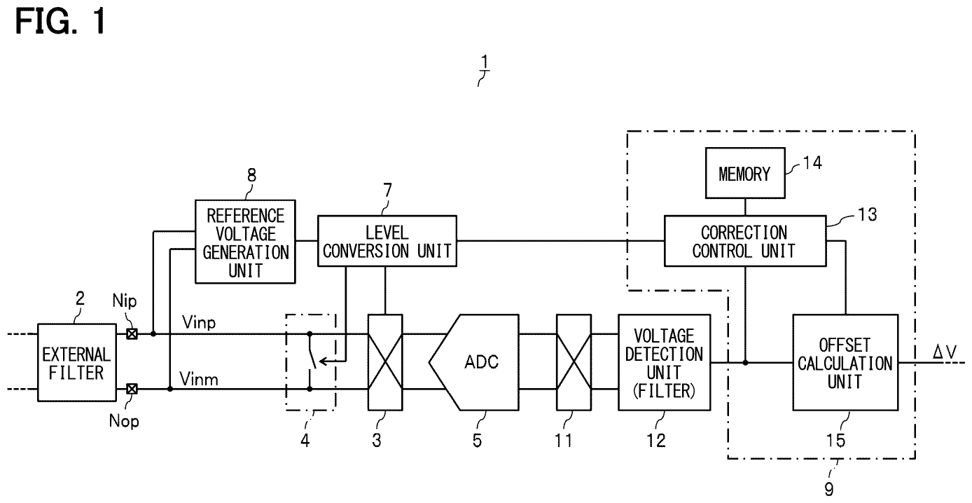

The following will describe embodiments of the present disclosure with reference to the accompanying drawings. In the following embodiments, substantially identical elements have the same numerals, and description of the identical elements will not be repeated. The first embodiment will be described below with reference to FIGS. 1 to 4.

### Overall Configuration

As shown in FIG. 1, a voltage detection circuit 1 of the present embodiment is a circuit that detects a differential voltage between the voltages at a pair of input nodes Nip and Nim. The voltage detection circuit 1 is used, for example, in a battery monitoring integrated circuit (IC) adapted to a vehicle such as an automobile. Although not shown in the drawing, the battery monitoring IC is an integrated circuit in which various circuits for performing various operations to monitor the status of a battery pack—such as the voltage of multiple battery cells connected in series in multiple stages—are integrated.

In this case, the voltage detection circuit 1 is intended to detect the voltage of a battery cell, and therefore, the voltage of the battery cell is supplied to the input nodes Nip and Nin. As described above, since the battery cells are connected in series in multiple stages together with other battery cells, a common-mode voltage is superimposed on each battery cell. This common mode voltage becomes higher toward the battery cell connected to the upper stage side of the battery pack, that is, to the high potential side, and its maximum value is a relatively high voltage of about several hundred volts, for example.

In addition, in this case, an external filter 2, which is an RC filter for removing noise, is provided in the preceding stage of the voltage detection circuit 1. That is, in this case, the voltage of the battery cell is supplied to the input nodes Nip and Nim via the external filter 2. The external filter 2 is, for example, a low-pass filter equipped with two resistors and one capacitor. In this specification, a low-pass filter may be referred to as an LPF.

The voltage detection circuit 1 has a differential configuration that samples the voltage Vinp at the input node Nip, which is the higher potential of the two input nodes Nip and Nin, and the voltage Vinm at the input node Nim, which is the lower potential, and detects the difference, as a differential voltage, between the voltages Vinp and Vinm. The voltage detection circuit 1 includes, for example, a chopper unit 3, an input short-circuit unit 4, an analog-to-digital (A/D) conversion unit 5, a digital chopper unit 11, a voltage detection unit 12, a level conversion unit 7, a reference voltage generation unit 8, and an offset correction unit 9. In the present disclosure, the chopper unit 3 corresponds to a chopper circuit; the input short-circuit unit 4 corresponds to an input shorting circuit; the A/D conversion unit 5 corresponds to an analog-to-digital conversion circuit; the digital chopper unit 11 corresponds to a digital chopper circuit; the voltage detection unit 12 corresponds to a detection circuit; the level conversion unit 7 corresponds to a level conversion circuit; the reference voltage generation unit 8 corresponds to a voltage generation circuit; and the offset correction unit 9 corresponds to an offset correction circuit.

The chopper unit 3 receives the respective voltages Vinp and Vinm from the pair of input nodes Nip and Nim, inverts the polarity of these voltages, and outputs them as Voutp and Voutm from the pair of output nodes Nop and Nom. Although details will be described later, the chopper unit 3 is configured with chopper switches connected between the pair of input nodes Nip and Nim and the pair of output nodes Nop and Nom. In the following description, the operation performed by the chopper unit 3 may be referred to as “chopping” or “chopper operation.”

The input short-circuit unit 4 is provided with a short-circuit switch connected between the pair of input nodes Nip and Nim, and is capable of performing a short-circuit operation that electrically shorts the pair of input nodes Nip and Nim. The operation of the input short-circuit unit 4 is controlled by the offset correction unit 9, which will be described later. The short-circuit operation by the input short-circuit unit 4 is executed, for example, during operation stoppage when the system equipped with the voltage detection circuit 1 is halted, or during inspection prior to shipment of the product equipped with the voltage detection circuit 1. In addition, the short-circuit operation by the input short-circuit unit 4 is not to be executed during normal operation when the system equipped with the voltage detection circuit 1 is performing its normal operation. The term “short-circuit” may also be referred to as “shorting” in the present disclosure. For example, the input short-circuit unit 4 may also be referred to as an input shorting unit or an input shorting circuit. The short-circuit operation may also be referred to as a shorting operation. The short-circuit switch may also be referred to as a shorting switch.

The A/D conversion unit 5 is, for example, a ΔΣ-type A/D converter that performs A/D conversion on the voltage output from the chopper unit 3. It should be noted that, in FIG. 1 and elsewhere, the A/D converter is abbreviated as “ADC.” The digital chopper unit 11 performs polarity inversion digitally and outputs a signal in which the input signal is inverted. The voltage detection unit 12 is formed with a digital filter and determines the detected value of the differential voltage described above based on the output signal from the A/D conversion unit 5. The filter of the voltage detection unit 12 is, for example, a low-pass filter (LPF) such as a moving average filter. The output signal of the filter in the voltage detection unit 12 is a digital value corresponding to the detected value of the differential voltage described above.

The level conversion unit 7 receives a first drive signal for driving the chopper switch provided in the chopper unit 3, and a second drive signal for driving the short-circuit switch provided in the input short-circuit unit 4. The level conversion unit 7 converts the level of the first drive signal and outputs it to the chopper unit 3, and also converts the level of the second drive signal and outputs it to the input short-circuit unit 4. The reference voltage generation unit 8 is connected between the pair of input nodes Nip and Nim. The reference voltage generation unit 8 generates a reference voltage for the level conversion unit 7 using the voltages Vinp and Vinm at the input nodes Nip and Nim, respectively.

The offset correction unit 9 corrects the offset in the detected value obtained by the voltage detection unit 12, and includes a correction control unit 13, a memory 14, and an offset subtraction unit 15. The correction control unit 13 is capable of controlling the on/off state of the short-circuit switch provided in the input short-circuit unit 4. The correction control unit 13 acquires, as an offset value, the detected value detected by the voltage detection unit 12 in a state where the pair of input nodes Nip and Nim are short-circuited by the input short-circuit unit 4.

In other words, the correction control unit 13 acquires the offset value during system downtime or during inspection prior to product shipment. The correction control unit 13 writes and stores the offset value thus obtained in the memory 14. During normal operation, the correction control unit 13 reads the offset value from the memory 14 and outputs it to the offset subtraction unit 15.

The offset subtraction unit 15 corrects the offset by subtracting the offset value provided from the correction control unit 13 from the detected value detected by the voltage detection unit 12 in a state where the pair of input nodes Nip and Nim are not connected by the input short-circuit unit 4. In this case, the signal output from the offset subtraction unit 15 becomes the final detected value ΔV of the differential voltage. In other words, the offset subtraction unit 15 corrects the offset by subtracting a predetermined offset value from the detected value detected by the voltage detection unit 12 during normal operation, and outputs the corrected value as the final detected value ΔV of the differential voltage.

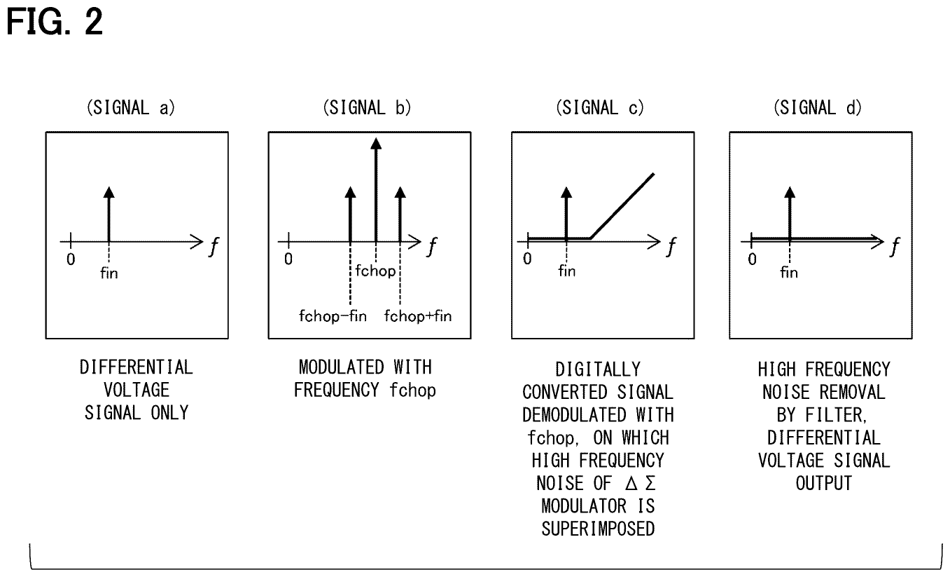

The signals at respective units of the voltage detection circuit 1 having the above configuration are as shown in FIG. 2. It should be noted that the horizontal axis in FIG. 2 represents the frequency f. That is, as shown in (Signal a) of FIG. 2, the signal provided to the chopper unit 3 consists only of the differential voltage signal. In FIG. 2, the frequency of the differential voltage signal is represented as fin.

As shown in (Signal b) of FIG. 2, the signal output from the chopper unit 3 and provided to the A/D conversion unit 5 is a signal modulated at the chopping frequency f_chop of the chopper unit 3. In other words, in the chopper unit 3, modulation is performed by analog polarity-reversal chopping. In the A/D conversion unit 5, the signal output from the chopper unit 3 is converted into a digital signal. In the digital chopper unit 11, demodulation is performed by digital polarity-reversal chopping.

As shown in (Signal c) of FIG. 2, the signal output from the digital chopper unit 6 and provide to the filter of the voltage detection unit 12 is a demodulated and digitally converted signal, and is also a signal on which high-frequency noise from the ΔΣ modulator of the A/D conversion unit 5 is superimposed. In the digital filter of the voltage detection unit 12, noise and other undesired components are removed. As shown in (Signal d) of FIG. 2, the signal output from the filter of the voltage detection unit 12 is a differential voltage signal from which high-frequency noise has been removed by the filter.

### Configuration of Chopper Unit

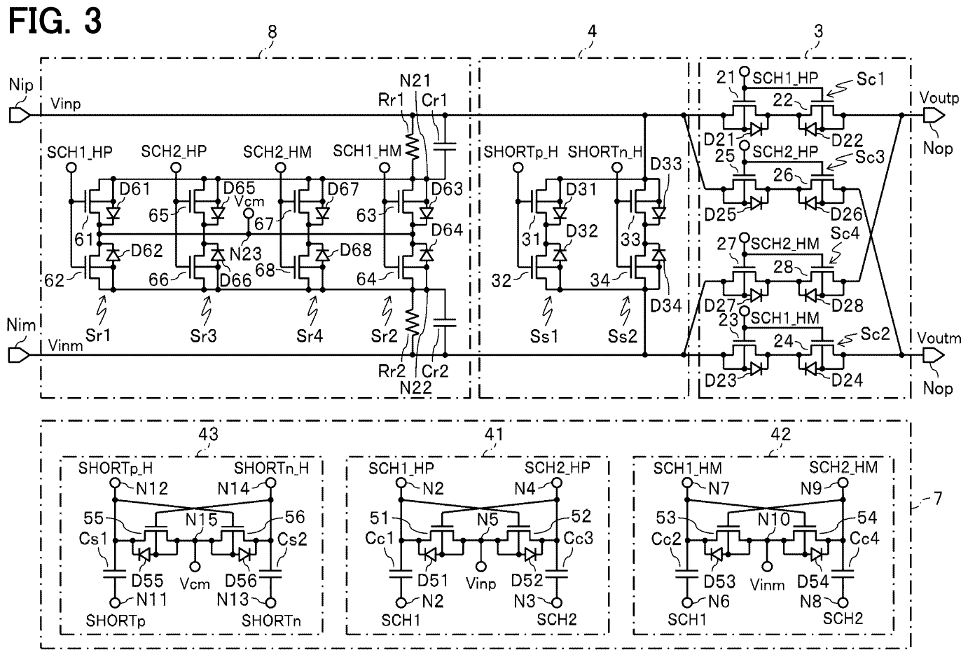

As a configuration of the chopper unit 3, for example, a configuration as shown in FIG. 3 can be employed. As shown in FIG. 3, in the chopper unit 3, the configuration corresponding to one of the pair of input nodes Nip and Nim, namely the input node Nip, and the configuration corresponding to the other input node Nim, are arranged symmetrically.

That is, the chopper unit 3 is provided with four chopper switches Sc1 to Sc4, which are connected between a pair of input nodes Nip and Nim and a pair of output nodes Nop and Nom. Although not shown in the drawing, a pair of sampling capacitors forming a differential configuration are connected to the pair of output nodes Nop and Nom. The chopper switches Sc1 to Sc4 can open and close the connections between the pair of input nodes Nip and Nim and the pair of output nodes Nop and Nom, and ultimately, the two sampling capacitors described above.

The chopper switch Sc1 is provided so as to be able to open and close the connection between the input node Nip and the output node Nop. One terminal of the chopper switch Sc1 is connected to the input node Nip, and the other terminal is connected to the output node Nop. The chopper switch Sc2 is provided so as to be able to open and close the connection between the input node Nim and the output node Nom. One terminal of the chopper switch Sc2 is connected to the input node Nim, and the other terminal is connected to the output node Nom.

The chopper switch Sc3 is provided so as to be able to open and close the connection between the input node Nip and the output node Nom. One terminal of the chopper switch Sc3 is connected to the input node Nip, and the other terminal is connected to the output node Nom. The chopper switch Sc4 is provided so as to be able to open and close the connection between the input node Nim and the output node Nop. One terminal of the chopper switch Sc4 is connected to the input node Nim, and the other terminal is connected to the output node Nop.

Each of the chopper switches Sc1 to Sc4 is formed by two MOSFETs whose drains are connected to each other and whose gates are connected to each other. In other words, each of the chopper switches Sc1 to Sc4 is formed by two MOSFETs arranged in a back-to-back, opposing configuration with a common drain. In the present embodiment, all of the MOSFETs included in the chopper switches Sc1 to Sc4 are N-channel MOSFETs. It should be noted that, in this specification, N-channel MOSFETs may sometimes be abbreviated as NMOS.

The chopper switch Sc1 is configured such that two NMOS transistors 21 and 22 are connected in series. The source of NMOS 21 is connected to the input node Nip, and the source of NMOS 22 is connected to the output node Nop. The drains of NMOS 21 and 22 are connected to each other. The gates of NMOS 21 and 22 are connected to each other. The back gate of NMOS 21 is connected to its source. The back gate of NMOS 22 is connected to its source.

A body diode D21, with its anode on the back gate side, exists between the back gate and drain of NMOS 21. A body diode D22, with its anode on the back gate side, exists between the back gate and drain of NMOS 22. In other words, in the chopper switch Sc1, the body diodes D21 and D22 are arranged facing each other. A drive signal SCH1_HP output from the level conversion unit 7 is applied to the gates of NMOS 21 and 22. As a result, the on/off states of NMOS 21 and 22 are controlled by the drive signal SCH1_HP. The drive signal SCH1_HP is a signal that functions as a first drive signal for driving the chopper switch S1.

The chopper switch Sc2 is formed with two NMOS transistors, NMOS 23 and 24, connected in series. The source of NMOS 23 is connected to the input node Nim, and the source of NMOS 24 is connected to the output node Nom. The drains of NMOS 23 and 24 are connected to each other. The gates of NMOS 23 and 24 are connected to each other. The back gate of NMOS 23 is connected to its source. The back gate of NMOS 24 is connected to its source.

A body diode D23, with its anode on the back gate side, exists between the back gate and drain of NMOS 23. A body diode D24, with its anode on the back gate side, exists between the back gate and drain of NMOS 24. In other words, in the chopper switch Sc2, the body diodes D23 and D24 are oriented in opposite directions to each other. A drive signal SCH1_HM output from the level conversion unit 7 is applied to the gates of NMOS 23 and 24. As a result, the on/off states of NMOS 23 and 24 are controlled by the drive signal SCH1_HM. The drive signal SCH1_HM is a signal that functions as a first drive signal for driving the chopper switch Sc2.

The chopper switch Sc3 is formed with two NMOS transistors, 25 and 26, connected in series. The source of NMOS 25 is connected to the input node Nip, and the source of NMOS 26 is connected to the output node Nom. The drains of NMOS 25 and 26 are connected to each other. The gates of NMOS 25 and 26 are connected to each other. The back gate of NMOS 25 is connected to its source. The back gate of NMOS 26 is connected to its source.

A body diode D25, with its anode on the back gate side, exists between the back gate and drain of NMOS 25. A body diode D26, with its anode on the back gate side, is present between the back gate and drain of NMOS 26. In other words, in the chopper switch Sc3, the body diodes D25 and D26 face each other. Each gate of NMOS 25 and 26 is supplied with the drive signal SCH2_HP output from the level conversion unit 7. As a result, the on/off states of NMOS 25 and 26 are controlled by the drive signal SCH2_HP. The drive signal SCH2_HP is a signal that functions as a first drive signal for driving the chopper switch Sc3.

The chopper switch Sc4 is formed with two NMOS transistors, 27 and 28, connected in series. The source of NMOS 27 is connected to the input node Nim, and the source of NMOS 28 is connected to the output node Nop. The drains of NMOS 27 and 28 are connected to each other. The gates of NMOS 27 and 28 are connected to each other. The back gate of NMOS 27 is connected to its source. The back gate of NMOS 28 is connected to its source.

A body diode D27, with its anode on the back gate side, exists between the back gate and the drain of NMOS 27. A body diode D28, with its anode on the back gate side, exists between the back gate and the drain of NMOS 28. In other words, in the chopper switch Sc4, the body diodes D27 and D28 are oriented in opposite directions to each other. Each gate of NMOS 27 and 28 is supplied with the drive signal SCH2_HM output from the level conversion unit 7. As a result, the on/off states of NMOS 27 and 28 are controlled by the drive signal SCH2_HM. The drive signal SCH2_HM is a signal that functions as a first drive signal for driving the chopper switch Sc4.

### Configuration of Input Short-Circuit Unit

As a configuration of the input short-circuit unit 4, for example, a configuration as shown in FIG. 3 may be adopted. As shown in FIG. 3, in the input short-circuit unit 4, the configuration corresponding to one of the pair of input nodes Nip and Nim, namely input node Nip, and the configuration corresponding to the other input node Nim of the pair of input nodes Nip and Nim, are arranged symmetrically.

That is, the input short-circuit unit 4 is provided with two short-circuit switches Ss1 and Ss2 connected between the pair of input nodes Nip and Nim. The short-circuit switches Ss1 and Ss2 are capable of connecting the pair of input nodes Nip and Nim. Although details will be described later, the input short-circuit unit 4 electrically shorts the pair of input nodes Nip and Nim by complementarily turning the two short-circuit switches Ss1 and Ss2 on and off. Furthermore, although details will be described later, the short-circuit switches Ss1 and Ss2 are driven in synchronization with the chopper switches S1 to S4 of the chopper unit 3.

The short-circuit switch Ss1 is provided so as to be able to open and close the circuit between the input nodes Nip and Nim. One terminal of the short-circuit switch Ss1 is connected to the input node Nip, and the other terminal is connected to the input node Nim. The short-circuit switch Ss2 is provided so as to be able to open and close the circuit between the input nodes Nip and Nim. One terminal of the short-circuit switch Ss2 is connected to the input node Nip, and the other terminal is connected to the input node Nim.

Both short-circuit switches Ss1 and Ss2 are each formed with two MOSFETs whose drains are connected to each other and whose gates are connected to each other. That is, both short-circuit switches Ss1 and Ss2 are formed with two MOSFETs in a back-to-back, opposing arrangement with a common drain. In this embodiment, the MOSFETs included in the short-circuit switches Ss1 and Ss2 are all N-channel MOSFETs (NMOS).

The short-circuit switch Ss1 is configured such that two NMOS transistors, 31 and 32, are connected in series. The source of NMOS 31 is connected to the input node Nip, and the source of NMOS 32 is connected to the input node Nim. The drains of NMOS 31 and NMOS 32 are connected to each other. The gates of NMOS 31 and NMOS 32 are connected to each other. The back gate of NMOS 31 is connected to its source. The back gate of NMOS 32 is connected to its source.

A body diode D31, with its anode on the back gate side, exists between the back gate and drain of NMOS 31. A body diode D32, with its anode on the back gate side, exists between the back gate and drain of NMOS 32. In other words, in the short-circuit switch Ss1, the body diodes D31 and D32 are oriented in opposition to each other. Each gate of NMOS 31 and 32 is supplied with the drive signal SHORTp_H output from the level conversion unit 7. As a result, the on/off states of NMOS 31 and 32 are controlled by the drive signal SHORTp_H. The drive signal SHORTp_H is a signal that functions as a second drive signal for driving the short-circuit switch S21.

The short-circuit switch Ss2 is formed with two NMOS transistors, 33 and 34, connected in series. The source of NMOS 33 is connected to the input node Nip, and the source of NMOS 34 is connected to the input node Nim. The drains of NMOS 33 and 34 are connected to each other. The gates of NMOS 33 and 34 are connected to each other. The back gate of NMOS 33 is connected to its source. The back gate of NMOS 34 is connected to its source.

A body diode D33, with its anode on the back gate side, exists between the back gate and drain of NMOS 33. A body diode D34, with its anode on the back gate side, exists between the back gate and drain of NMOS 34. That is, in the short-circuit switch Ss2, the body diodes D33 and D34 are oriented in opposition to each other. A drive signal SHORTn_H, output from the level conversion unit 7, is supplied to each gate of NMOS 33 and 34. As a result, the on/off states of NMOS 33 and 34 are controlled by the drive signal SHORTn_H. The drive signal SHORTn_H is a signal that functions as a second drive signal for driving the short-circuit switch Ss2.

### Configuration of Level Conversion Unit

As a configuration of the level conversion unit 7, for example, a configuration as shown in FIG. 3 can be employed. As shown in FIG. 3, in the level conversion unit 7, the configuration corresponding to one of the pair of input nodes Nip and Nim, namely the input node Nip, and the configuration corresponding to the other input node Nim of the pair, are arranged in a symmetrical structure.

That is, the level conversion unit 7 is provided with capacitive coupling switches 41, 42, and 43, and converts the levels of the drive signals SCH1, SCH2, SHORTp, and SHORTn, which are provided from outside, using these capacitive coupling switches 41 to 43. Specifically, the level conversion unit 7 converts the levels of the drive signals SCH1 and SCH2 using the capacitive coupling switch 41, and outputs them as drive signals SCH1_HP and SCH2_HP. The level conversion unit 7 converts the levels of the drive signals SCH1 and SCH2 using the capacitive coupling switch 42, and outputs them as drive signals SCH1_HM and SCH2_HM. The level conversion unit 7 converts the levels of the drive signals SHORTp and SHORTn using the capacitive coupling switch 43, and outputs them as drive signals SHORTp_H and SHORTn_H.

The drive signals SCH1 and SCH2 function as first drive signals. The drive signals SHORTp and SHORTn function as second drive signals. The level conversion unit 7 controls the operation of the chopper switches Sc1 to Sc4 and the short-circuit switches Ss1 and Ss2 based on the drive signals SCH1, SCH2, SHORTp, and SHORTn. The drive signals SCH1, SCH2, SHORTp, and SHORTn are all binary signals, with their high level at +5V and their low level at 0V.

The capacitive coupling switch 41 performs level shifting of the drive signals SCH1 and SCH2 based on the voltage Vinp at the input node Nip as a reference. The capacitive coupling switch 42 performs level shifting of the drive signals SCH1 and SCH2 using the voltage Vinm at the input node Nim as a reference. The capacitive coupling switch 43 performs level shifting of the drive signals SHORTp and SHORTn using the reference voltage Vcm, which is output from the reference voltage generation unit 8 described later, as a reference.

The capacitive coupling switch 41 includes drive capacitors Cc1 and Cc3, which are provided corresponding to switches Sc1 and Sc3, respectively. The capacitive coupling switch 41 controls the on/off operation of the chopper switch Sc1 by driving the gates of NMOS 21 and 22 via the drive capacitor Cc1, and controls the on/off operation of the chopper switch Sc3 by driving the gates of NMOS 25 and 26 via the drive capacitor Cc3.

The drive capacitor Cc1 is connected between node N1, which is the input node for the drive signal SCH1, and node N2, which is the output node for the drive signal SCH1_HP. The node N2 is connected to the gates of NMOS 21 and 22. The drive capacitor Cc3 is connected between the node N3, which is the input node for the drive signal SCH2, and the node N4, which is the output node for the drive signal SCH2_HP. The node N4 is connected to the gates of the NMOS 25 and 26. In the present embodiment, the drive capacitors Cc1 and Cc3 are formed, for example, as interdigitated (comb-shaped) capacitors.

The capacitive coupling switch 41 includes two NMOS transistors 51, 52. The drain of the NMOS 51 is connected to the node N2, and its source is connected to the node N5. The node N5 is supplied with the voltage Vinp from the input node Nip. The back gate of NMOS 51 is connected to its source. The gate of the NMOS 51 is connected to the node N4. A body diode D51, with its anode on the back gate side, exists between the back gate and drain of NMOS 51.

The drain of the NMOS 52 is connected to the node N4, and its source is connected to the node N5. The back gate of NMOS 52 is connected to its source. The gate of NMOS 52 is connected to the node N2. A body diode D52, with its anode on the back gate side, exists between the back gate and drain of NMOS 52.

The capacitive coupling switch 41 with the above configuration is designed to generate a drive signal SCH1_HP for driving the gates of the NMOS 21 and 22 using the voltage Vinp of input node Nip as a reference potential, as well as a drive signal SCH2_HP for driving the gates of the NMOS 25 and 26. The drive signal SCH1_HP has the same logic as the drive signal SCH1, and is provided from the node N2 to the gates of NMOS 21 and 22 in the chopper switch Sc1. The drive signal SCH2_HP has the same logic as the drive signal SCH2, and is supplied from the node N4 to the gates of the NMOS 25 and 26 in the chopper switch Sc3.

The capacitive coupling switch 42 is provided with drive capacitors Cc2 and Cc4 corresponding to switches Sc2 and Sc4, respectively. The capacitive coupling switch 42 controls the on/off states of the chopper switch Sc2 by driving the gates of the NMOS 23 and 24 via the drive capacitor Cc2, and controls the on/off states of the chopper switch Sc4 by driving the gates of the NMOS 27 and 28 via the drive capacitor Cc4.

The drive capacitor Cc2 is connected between node N6, which is the input node for the drive signal SCH1, and node N7, which is the output node for the drive signal SCH1_HM. The node N7 is connected to the gates of the NMOS 23 and 24. The drive capacitor Cc4 is connected between node N8, which is the input node for the drive signal SCH2, and node N9, which is the output node for the drive signal SCH2_HM. The node N9 is connected to the gates of the NMOS 27 and 28. In the present embodiment, the drive capacitors Cc2 and Cc4 are formed, for example, by interdigitated (comb-tooth) capacitors.

The capacitive coupling switch 42 includes two NMOS transistors 53, 54. The drain of NMOS 53 is connected to the node N7, and its source is connected to the node N10. The node N10 is supplied with the voltage Vinm of the input node Nim. The back gate of NMOS 53 is connected to its source. The gate of NMOS 53 is connected to the node N9. A body diode D53, with its anode on the back gate side, exists between the back gate and drain of NMOS 53.

The drain of NMOS 54 is connected to the node N9, and its source is connected to the node N10. The back gate of the NMOS 54 is connected to its source. The gate of the NMOS 54 is connected to the node N7. A body diode D54, with its anode on the back gate side, exists between the back gate and drain of NMOS 54.

The capacitive coupling switch 42 with the above configuration is designed to generate a drive signal SCH1_HM for driving the gates of NMOS 23 and 24 using the voltage Vinm of input node Nim as a reference potential, as well as a drive signal SCH2_HM for driving the gates of the NMOS 27 and 28. The drive signal SCH1_HM has the same logic as the drive signal SCH1 and is supplied from the node N7 to the gates of NMOS 23 and 24 in the chopper switch Sc2. The drive signal SCH2_HM has the same logic as the drive signal SCH2 and is supplied from the node N9 to the gates of NMOS 27 and 28 in the chopper switch Sc4.

The capacitively coupled switch 43 is provided with drive capacitors Cs1 and Cs2, each corresponding to the short-circuit switches Ss1 and Ss2, respectively. The capacitively coupled switch 43 controls the on/off states of the short-circuit switch Ss1 by driving the gates of NMOS 31 and 32 via the drive capacitor Cs1, and controls the on/off states of the short-circuit switch Ss2 by driving the gates of NMOS 33 and 34 via the drive capacitor Cs2.

The drive capacitor Cs1 is connected between node N11, which is the input node for the drive signal SHORTp, and node N12, which is the output node for the drive signal SHORTp_H. The node N12 is connected to the gates of NMOS 31 and 32. The drive capacitor Cs2 is connected between node N13, which is the input node for the drive signal SHORTn, and node N14, which is the output node for the drive signal SHORTn_H. The node N14 is connected to the gates of NMOS 33 and 34. In the present embodiment, the drive capacitors Cs1 and Cs2 are formed, for example, using comb capacitors.

The capacitive coupling switch 43 includes two NMOS transistors 55, 56. The drain of NMOS 55 is connected to the node N12, and its source is connected to node N15. The node N15 is supplied with the reference voltage Vcm, which is output from the reference voltage generation unit 8 described later. The back gate of NMOS 55 is connected to its source. The gate of NMOS 55 is connected to the node N14. A body diode D55, with its anode on the back gate side, exists between the back gate and the drain of NMOS 55.

The drain of NMOS 56 is connected to the node N14, and its source is connected to node N15. The back gate of NMOS 56 is connected to its source. The gate of NMOS 56 is connected to the node N12. A body diode D56, with its anode on the back gate side, exists between the back gate and the drain of NMOS 56.

The capacitive coupling switch 43 of the above configuration is designed to generate a drive signal SHORTp_H for driving the gates of NMOS 31 and 32, with the reference voltage Vcm as the reference potential, and a drive signal SHORTn_H for driving the gates of NMOS 33 and 34. The drive signal SHORTp_H has the same logic as the drive signal SHORTp and is supplied from node N12 to the gates of NMOS 31 and 32 of the short-circuit switch Ss1. The drive signal SHORTn_H has the same logic as the drive signal SHORTn and is supplied from node N14 to the gates of NMOS 33 and 34 of the short-circuit switch Ss2.

With the above configuration, the capacitive coupling switches 41 to 43 provide the drive signals SCH1_HP, SCH2_HP, SCH1_HM, SCH2_HM, SHORTp_H, and SHORTn_H, respectively, to each gate of NMOS 21 to 28, 31 to 34, which are included in the chopper switches Sc1 to Sc4 and the short-circuit switches Ss1 and Ss2. The drive signals SCH1_HP, SCH2_HP, SCH1_HM, SCH2_HM, SHORTp_H, and SHORTn_H are binary signals that take either the off level, which turns off NMOS 21 to 28 and 31 to 34, or the on level, which turns on NMOS 21 to 28 and 31 to 34.

The above-mentioned on level is a level that satisfies equation (1) below, and the above-mentioned off level is a level that satisfies equation (2) below. Here, let VGS denote the gate-source voltage of the NMOS, and Vt denote the threshold voltage of the NMOS.
VGS>Vt (1)
VGS≈0 (2)

### Configuration of Reference Voltage Generation Unit

As a configuration of the reference voltage generation unit 8, for example, a configuration as shown in FIG. 3 may be adopted. The reference voltage generation unit 8 includes resistors Rr1 and Rr2, capacitors Cr1 and Cr2, and four reference voltage switches Sr1, Sr2, Sr3, and Sr4. One terminal of resistor Rr1 is connected to the input node Nip, and the other terminal is connected to node N21. One terminal of resistor Rr2 is connected to the node N21, and the other terminal is connected to the input node Nim.

One terminal of the capacitor Cr1 is connected to the input node Nip, and the other terminal is connected to the node N21. One terminal of the capacitor Cr2 is connected to node N22, and the other terminal is connected to input node Nim. Each of the reference voltage switches Sr1 to Sr4 is connected between the nodes N21 and N22. In this manner, in the reference voltage generation unit 8, each of resistors Rr1, Rr2 and reference voltage switches Sr1 to Sr4 is connected in series between the pair of input nodes Nip and Nim.

A reference voltage switch Sr1 is driven using the drive signal SCH1_HP for driving the chopper switch Sc1. A reference voltage switch Sr2 is driven using the drive signal SCH1_HM for driving the chopper switch Sc2. A reference voltage switch Sr3 is driven using the drive signal SCH2_HP for driving the chopper switch Sc3. A reference voltage switch Sr4 is driven using the drive signal SCH2_HM for driving the chopper switch Sc4.

Each of the reference voltage switches Sr1 to Sr4 can be formed using two MOSFETs with their sources or drains connected to each other. In the present embodiment, each of the reference voltage switches Sr1 to Sr4 is configured using two MOSFETs with their drains connected to each other. That is, each of the reference voltage switches Sr1 to Sr4 is configured with two MOSFETs in a back-to-back, opposing arrangement, and with a common drain. In the present embodiment, all of the MOSFETs included in the reference voltage switches Sr1 to Sr4 are NNMOS.

The reference voltage switch Sr1 has a configuration in which two NMOS transistors 61 and 62 are connected in series. The source of NMOS 61 is connected to node N21, and the source of NMOS 62 is connected to node N22. The drains of NMOS 61 and 62 are connected to each other and also to node N23. The node N23 is the output node of the reference voltage Vcm. The gates of NMOS 61 and 62 are connected to each other. The back gate of NMOS 61 is connected to its source. The back gate of NMOS 62 is connected to its source.

A body diode D61, with its anode on the back gate side, exists between the back gate and drain of NMOS 61. A body diode D62, with its anode on the back gate side, exists between the back gate and drain of NMOS 62. That is, in the reference voltage switch Sr1, the body diodes D61 and D62 are oriented in opposition to each other. A drive signal SCH1_HP is applied to each gate of NMOS 61 and 62. As a result, the on/off states of NMOS 61 and 62 are controlled by the drive signal SCH1_HP.

The reference voltage switch Sr2 has a configuration in which two NMOS transistors 63, 64 are connected in series. The source of NMOS 63 is connected to the node N21, and the source of NMOS 64 is connected to the node N22. The drains of NMOS 61 and 62 are connected to each other and also to node N23. The gates of NMOS 63 and 64 are connected to each other. The back gate of NMOS 63 is connected to its source. The back gate of NMOS 63 is connected to its source.

A body diode D63, with its anode on the back gate side, exists between the back gate and drain of NMOS 63. A body diode D63, with its anode on the back gate side, exists between the back gate and drain of NMOS 63. That is, in the reference voltage switch Sr2, the body diodes D63 and D64 are oriented opposite to each other. The gates of NMOS 63 and 64 are supplied with the drive signal SCH1_HM. As a result, the on/off states of NMOS 63 and 64 are controlled by the drive signal SCH1_HM.

The reference voltage switch Sr3 has a configuration in which two NMOS transistors 65, 66 are connected in series. The source of NMOS 65 is connected to the node N21, and the source of NMOS 66 is connected to the node N22. The drains of NMOS 65 and 66 are connected to each other, and are also connected to the node N23. The gates of NMOS 65 and 66 are connected to each other. The back gate of NMOS 65 is connected to its source. The back gate of NMOS 66 is connected to its source.

A body diode D65, with its anode on the back gate side, exists between the back gate and drain of NMOS 65. A body diode D66, with its anode on the back gate side, exists between the back gate and drain of NMOS 66. That is, in the reference voltage switch Sr3, the body diodes D65 and D66 are oriented in opposition to each other. A drive signal SCH2_HP is applied to the gates of NMOS 65 and 66. As a result, the on/off states of NMOS 65 and 66 are controlled by the drive signal SCH2_HP.

The reference voltage switch Sr4 has a configuration in which two NMOS 67 and 68 are connected in series. The source of NMOS 67 is connected to the node N21, and the source of NMOS 68 is connected to the node N22. The drains of NMOS 67 and 68 are connected to each other and also to the node N23. The gates of NMOS 67 and 68 are connected to each other. The back gate of NMOS 67 is connected to its source. The back gate of NMOS 68 is connected to its source.

A body diode D67, with its anode on the back gate side, exists between the back gate and drain of NMOS 67. A body diode D68, with its anode on the back gate side, exists between the back gate and drain of NMOS 68. In other words, in the reference voltage switch Sr4, the body diodes D67 and D68 are oriented in opposition to each other. A drive signal SCH2_HM is applied to each gate of NMOS 67 and 68. As a result, the on/off states of NMOS 67 and 68 are controlled by the drive signal SCH2_HM.

With such a configuration, the reference voltage generation unit 8 can generate the reference voltage Vcm, which is an intermediate potential between the respective voltages Vip and Vim of the pair of input nodes Nip and Nim, by driving the reference voltage switches Sr1 to Sr4 using the drive signals SCH1_HP, SCH1_HM, SCH2_HP, and SCH2_HM that are used to drive the chopper switches Sc1 to Sc4.

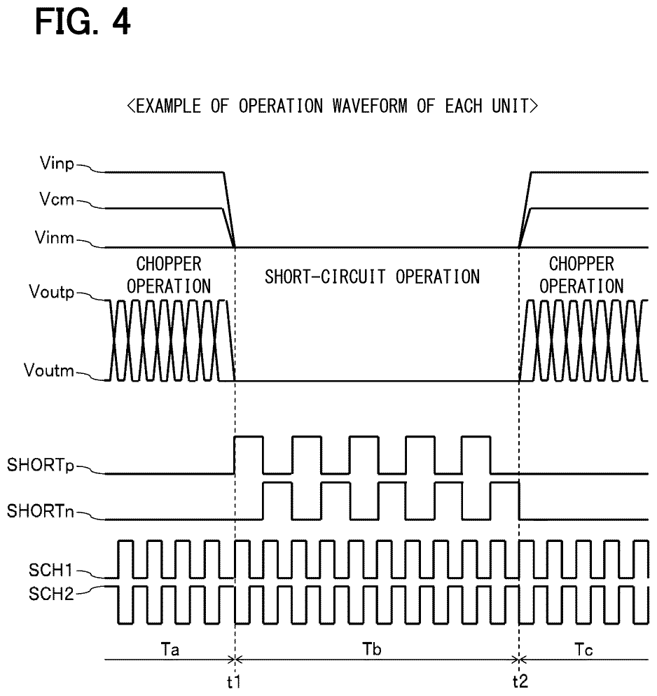

Next, the operation of the above configuration will be explained with reference to FIG. 4. FIG. 4 is a timing chart illustrating an example of operational waveforms of each unit. In FIG. 4, the period Ta before time t1 and the period Tc after time t2 correspond to the aforementioned normal operation, while the period Tb from time t1 to time t2 corresponds to the aforementioned operation stop or inspection, etc. In FIG. 4, the drive signals SHORTp, SHORTn, SCH1, and SCH2 indicate that the relatively high level, or high level, represents the level that turns on the target MOSFET, while the relatively low level, or low level, represents the level that turns off the target MOSFET.

During periods Ta and Tc, since the drive signals SHORTp and SHORTn are fixed at the low level, the short-circuit operation by the input short-circuit unit 4 is not executed. During periods Ta and Tc, since the drive signals SCH1 and SCH2 alternately go to the high level, the chopper switches Sc1 and Sc2, and the chopper switches Sc3 and Sc4, are turned on and off in a complementary manner. It should be noted that the term “turned on and off in a complementary manner” as used in this specification does not exclude cases where there is a period during which both switches are off, i.e., a so-called dead time is provided.

As a result, during periods Ta and Tc, the chopping operation by the chopper unit 3 is executed. Therefore, during periods Ta and Tc, the voltages Voutp and Voutm exhibit waveforms that alternately change between a relatively high level and a relatively low level. Further, during periods Ta and Tc, the reference voltage generation unit 8 generates the reference voltage Vcm by operating using the drive signals SCH1_HP, SCH1_HM, SCH2_HP, and SCH2_HM, which are obtained by level-shifting the drive signals SCH1 and SCH2. The reference voltage Vcm serves as the intermediate voltage between the voltages Vinp and Vinm at the input nodes Nip and Nim.

During period Tb, since the drive signals SHORTp and SHORTn alternately go high, the short-circuit switches Ss1 and Ss2 are turned on and off complementarily. As a result, during period Tb, the short-circuit operation by the input short-circuit unit 4 is carried out, and the input nodes Nip and Nim are short-circuited. The drive signals SHORTp and SHORTn are signals synchronized with the drive signals SCH1 and SCH2, thereby enabling the short-circuit switches Ss1 and Ss2 to be driven in synchronization with the chopper switches Sc1 to Sc4. The cycle of the drive signals SHORTp and SHORTn is, for example, approximately twice as long as the cycle of the drive signals SCH1 and SCH2.

According to the present embodiment described above, the following effects can be obtained. The voltage detection circuit 1 of the present embodiment does not include a selector as in the comparative fully differential voltage detection circuit described above, so the offset can be suppressed to a smaller value compared to the comparative fully differential voltage detection circuit. Furthermore, according to the configuration of the present embodiment, when the input short-circuit unit 4 and the reference voltage generation unit 8 are not operated, the impedance of the circuit as seen from the input side becomes relatively high, resulting in a smaller amount of current flowing in. As a result, the input offset before correction can be reduced.

Furthermore, in the present embodiment, each of the chopper unit 3, the input short-circuit unit 4, and the level conversion unit 7 is configured symmetrically such that the configuration corresponding to one of the pair of input nodes Nip and Nim and the configuration corresponding to the other of the pair of input nodes Nip and Nim are symmetrical. Therefore, in the configuration of the present embodiment, during normal operation, the balance of the amount of current flowing through each of the pair of input nodes Nip and Nim can be maintained, so these currents do not become a factor causing offset. In this respect as well, the offset can be reduced, which in turn leads to improved accuracy of A/D conversion. Furthermore, according to the configuration of the present embodiment, since the offset is corrected by the offset correction unit 9, the offset can be further suppressed to an even smaller value. Therefore, according to the present embodiment, the accuracy of voltage detection can be improved.

In the present embodiment, the level conversion unit 7 converts the levels of the drive signals SCH1, SCH2 and the drive signals SHORTp, SHORTn using capacitive coupling switches 41 to 43. With such a configuration, it is suitable for applications in which a relatively high common-mode voltage is superimposed on each of the voltages Vip and Vim at the input nodes Nip and Nim.

In the present embodiment, the chopper switches Sc1 to Sc4 of the chopper unit 3, the short-circuit switches Ss1 and Ss2 of the input short-circuit unit 4, and the reference voltage switches Sr1 to Sr4 of the reference voltage generation unit 8 are all formed using two MOSFETs arranged in a back-to-back opposing configuration. With such a configuration, backflow can be prevented in the chopper unit 3, the input short-circuit unit 4, and the reference voltage generation unit 8.

In the present embodiment, the input short-circuit unit 4 is provided with two short-circuit switches Ss1 and Ss2, and by complementarily turning these two short-circuit switches Ss1 and Ss2 on and off, the pair of input nodes Nip and Nim are short-circuited. With such a configuration, the following effects can be obtained. That is, even when performing a short-circuit operation, the short-circuit switches Ss1 and Ss2 cannot remain constantly on in order to resolve an issue caused by leakage in the level conversion unit 7, and therefore must be appropriately turned off as necessary.

Although it is possible to configure the input short-circuit unit 4 with only one of the short-circuit switches Ss1 or Ss2, in such a case, it would be necessary to relatively lengthen the on-period of the single short-circuit switch and shorten its off-period. However, this would become a factor in generating errors. In contrast, according to the configuration of the present embodiment in which the two short-circuit switches Ss1 and Ss2 are alternately driven, it becomes possible to make the on-period and off-period of these short-circuit switches Ss1 and Ss2 equal, thereby resolving problems caused by leakage in the level conversion unit 7 while also suppressing errors to a minimum.

In the present embodiment, the short-circuit switches Ss1 and Ss2 are driven in synchronization with the chopper switches Sc1 to Sc4. By doing so, the following effects can be obtained. That is, if the short-circuit switches Ss1 and Ss2 are not driven in synchronization with the chopper switches Sc1 to Sc4, there is a possibility that the input nodes Nip and Nim may be short-circuited at unintended timings.

In contrast, according to the present embodiment, it is possible to prevent the input nodes Nip and Nim from being short-circuited at such unintended timings. As a result, the occurrence of imbalance between the input nodes Nip and Nim can be prevented, thereby reducing detection errors. Furthermore, with the configuration in which synchronization is achieved as in the present embodiment, there is also the advantage that the timing design of the drive signals SHORTp and SHORTn for driving the short-circuit switches Ss1 and Ss2, as well as the drive signals SCH1 and SCH2, becomes easier.

In the present embodiment, the MOSFETs constituting the chopper switches Sc1 to Sc4, the short-circuit switches Ss1 and Ss2, the reference voltage switches Sr1 to Sr4, and the capacitive coupling switches 41 to 43 are all N-channel MOSFETs. With such a configuration, since no different types of elements are present, there is an advantage in terms of the area of the IC on which the voltage detection circuit 1 is provided. That is, according to the above configuration, since only N-channel MOSFETs are used and no P-channel MOSFETs are present, it is not necessary to form trenches, and as a result, the area can be reduced accordingly.

### Second Embodiment

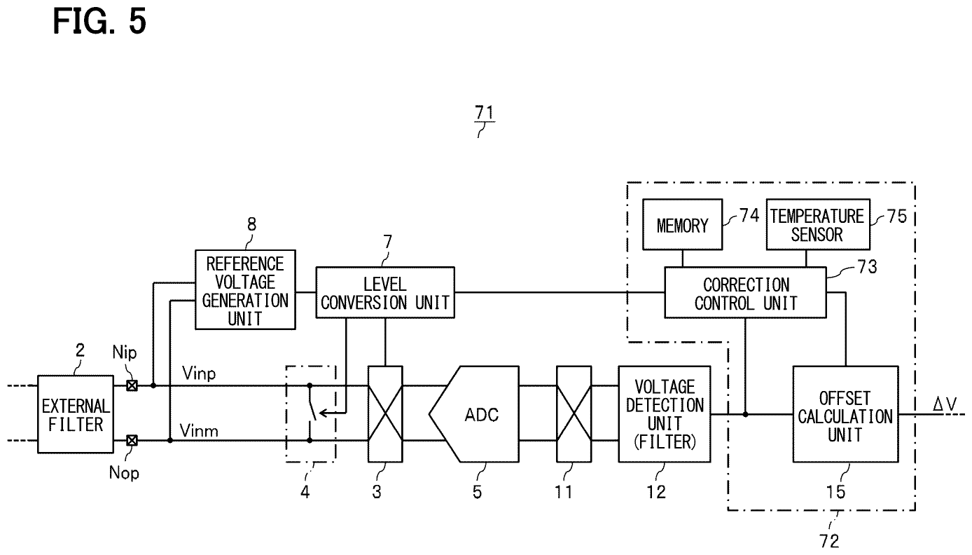

The second embodiment will be described below with reference to FIGS. 5 to 7. As shown in FIG. 5, an offset correction unit 72 included in a voltage detection circuit 71 of the present embodiment differs from the offset correction unit 9 of the first embodiment in that, instead of the correction control unit 13 and memory 14, it is provided with a correction control unit 73 and memory 74, and in addition, a temperature sensor 75 has been added. The temperature sensor 75 is capable of detecting the temperature of the voltage detection circuit 1, specifically, the temperature of the semiconductor chip on which the voltage detection circuit 1 is provided. The temperature sensor 75 outputs a temperature detection value, representing the detected temperature, to the correction control unit 73.

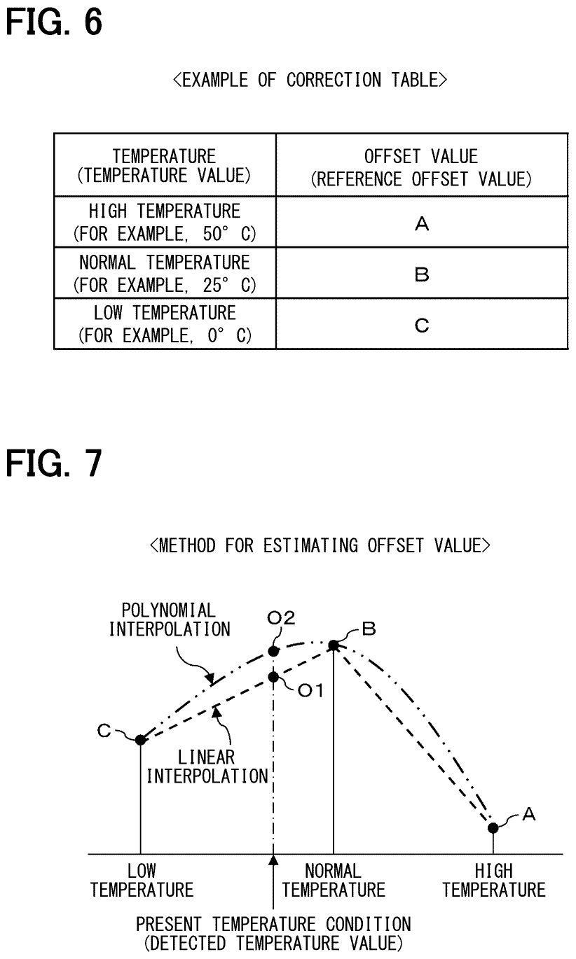

The memory 74 stores, in addition to the same information as the memory 14, a reference offset value, which is an offset value obtained under predetermined temperature conditions, and the temperature value corresponding to that reference offset value. Specifically, the memory 74 stores a correction table as shown in FIG. 6. In the correction table, the “offset value” corresponds to the reference offset value described above, and the “temperature” corresponds to the temperature value described above.

That is, the correction table stores, for example, a reference offset value A, which is an offset value obtained at a “high temperature” of 50 °C; a reference offset value B, which is an offset value obtained at a “normal temperature” of 25 °C; and a reference offset value C, which is an offset value obtained at a “low temperature” of 0 °C. The three reference offset values A to C can be measured, for example, at the time of factory shipment of the product in which the voltage detection circuit 71 is provided. Then, in a predetermined process such as during factory shipment, a correction table is written into the memory 74, in which the reference offset values A to C are linked to their respective temperature conditions, namely “high temperature,” “normal temperature,” and “low temperature.” The normal temperature may also be referred to as a room temperature.

The correction control unit 73 estimates the offset value under the current temperature condition using the reference offset values and temperature values stored in the memory 74, as well as the temperature detection value detected by the temperature sensor 75. Such estimation can be performed, for example, by using a correction formula such as a linear interpolation formula or a polynomial interpolation formula. Specifically, as shown in FIG. 7, when the temperature detection value is between “low temperature” and “normal temperature,” the offset value under such temperature conditions will be O1 according to linear interpolation (as indicated by the dotted line in FIG. 7), and O2 according to polynomial interpolation (as indicated by the two-dot chain line in FIG. 7). It is also possible to store such correction formulas in advance in memory 74.

The offset correction unit 72 can perform offset correction using the offset value estimated in this manner. That is, the correction control unit 73 estimates the offset value during normal operation as described above, and outputs the estimated offset value to the offset subtraction unit 15. The offset subtraction unit 15 corrects the offset by subtracting the offset value provided by the correction control unit 73 from the detection value detected by the voltage detection unit 12, in a state where the pair of input nodes Nip and Nim are not connected by the input short-circuit unit 4.

According to the present embodiment described above, the following effects can be obtained. The offset correction unit 72 of the present embodiment estimates the offset value under the current temperature condition by using the reference offset value and corresponding temperature value stored in the memory 74—which holds the reference offset value acquired under predetermined temperature conditions and the temperature value corresponding to the reference offset value—as well as the temperature detection value detected by the temperature sensor 75, and performs offset correction using the estimated offset value. With such a configuration, it becomes possible to perform correction according to the temperature dependence of the offset, thereby suppressing the offset regardless of temperature conditions and, consequently, improving the accuracy of voltage detection.

### Other Embodiments

It should be noted that the present invention is not limited to the embodiments described above and illustrated in the drawings, but may be modified, combined, or extended as desired within the scope of the invention without departing from its gist. The numerical values and the like shown in each of the above embodiments are merely examples and are not limited thereto.

In the second embodiment, the correction table stored in the memory 74 contains reference offset values corresponding to each of three temperature conditions; however, it is also possible to store reference offset values corresponding to each of four or more temperature conditions. For example, if a correction table storing reference offset values for each 1 °C increment within the expected temperature range is stored in the memory 74, the correction control unit 73 does not need to estimate the offset value under the current temperature condition using the correction formula, and can instead use the reference offset value stored in the correction table directly as the offset value.

The chopper switches Sc1 to Sc4 may also be constituted by two MOSFETs with their sources connected to each other and their gates connected to each other. That is, the chopper switches Sc1 to Sc4 may also be configured by two MOSFETs arranged in a back-to-back, opposing configuration with a common source. The short-circuit switches Ss1 and Ss2 may also be constituted by two MOSFETs with their sources connected to each other and their gates connected to each other. That is, the short-circuit switches Ss1 and Ss2 may also be configured by two MOSFETs arranged in a back-to-back, opposing configuration with a common source. The reference voltage switches Sr1 to Sr4 may also be configured by two MOSFETs arranged in a back-to-back, opposing configuration with a common source.

In each of the embodiments described above, the MOSFETs constituting the chopper switches Sc1 to Sc4, the short-circuit switches Ss1 and Ss2, the reference voltage switches Sr1 to Sr4, and the capacitive coupling switches 41 to 43 are all N-channel MOSFETs, but they may all instead be P-channel MOSFETs. In this case as well, the area can similarly be kept small.

The present disclosure has been described in accordance with the embodiments, but it is understood that the present disclosure is not limited to these embodiments or structures. The present disclosure also encompasses various modifications and equivalents within the scope thereof. In addition, various combinations and forms, as well as other combinations and forms that include only one element, more than one element, or fewer elements, are also within the scope and spirit of the present disclosure.

What is claimed is:

1. A voltage detection circuit configured to detect a differential voltage between a pair of input nodes of the voltage detection circuit, the voltage detection circuit comprising:
a chopper circuit having a chopper switch connected between the pair of input nodes and a pair of output nodes of the voltage detection circuit, the chopper circuit configured to
receive voltages at the pair of input nodes,
invert polarities of the voltages, and
output the voltages with inverted polarities from the pair of output nodes;
an input shorting circuit having a shorting switch connected between the pair of input nodes and configured to electrically short the pair of input nodes;
an analog-to-digital conversion circuit configured to perform analog-to-digital conversion on the voltages output from the chopper circuit;
a detection circuit configured to detect a value of the differential voltage based on an output signal of the analog-to-digital conversion circuit;
a level conversion circuit configured to
convert a level of a first drive signal for driving the chopper switch and a level of a second drive signal for driving the shorting switch, and
output the converted level of the first drive signal and the converted level of the second drive signal;
a reference voltage generation circuit configured to generate a reference voltage for the level conversion circuit; and
an offset correction circuit configured to correct an offset in the detected value by performing an offset correction, the offset correction including
acquiring, as an offset value, a first value of the differential voltage, the first value being detected by the detection circuit when the pair of input nodes is electrically shorted by the input shorting circuit, and
subtracting the offset value from a second value of the differential voltage, the second value being detected by the detection circuit when the pair of input nodes is not electrically shorted by the input shorting circuit.

2. The voltage detection circuit according to claim 1, wherein
the level conversion circuit includes a capacitive coupling switch configured to convert the level of the first drive signal and the level of the second drive signal.

3. The voltage detection circuit according to claim 2,
the reference voltage generation circuit includes a resistor and a reference voltage switch that are connected in series between the pair of input nodes,
the reference voltage switch includes two metal-oxide-semiconductor field-effect transistors, with respective sources or respective drains of the two metal-oxide-semiconductor field-effect transistors being connected together,
the reference voltage generation circuit configured to generate the reference voltage being an intermediate voltage between the voltages at the pair of the input nodes, by driving the reference voltage switch with the first drive signal, and
the level conversion circuit is configured to convert the level of the second drive signal with reference to the reference voltage.

4. The voltage detection circuit according to claim 1, wherein,
respective circuitry structures associated with the pair of input nodes are arranged symmetrically in each of the chopper circuit, the input shorting circuit, and the level conversion circuit.

5. The voltage detection circuit according to claim 1, wherein
each of the chopper switch and the shorting switch includes two metal-oxide-semiconductor field-effect transistors,
respective sources or respective drains of the two metal-oxide-semiconductor field-effect transistors are connected together, and
respective gates of the two metal-oxide-semiconductor field-effect transistors are connected together.

6. The voltage detection circuit according to claim 1, wherein
the offset correction circuit includes:
a temperature sensor configured to detect a temperature; and
a memory configured to store
a reference offset value, which is the offset value acquired under a predetermined temperature condition, and
a temperature value that corresponds to the reference offset value,
the offset correction further includes:
estimating the offset value under a present temperature condition based on
the reference offset value and the temperature value that are stored in the memory, and
a value of the temperature detected by the temperature sensor; and
subtracting the estimated offset value from the second value.

7. The voltage detection circuit according to claim 1, wherein
the shorting switch in the input shorting circuit is one of two shorting switches, and
the two shorting switches are configured to be turned on and off in a complementary manner to electrically short the pair of input nodes.

8. The voltage detection circuit according to claim 1, wherein
the shorting switch is configured to be driven in synchronization with the chopper switch.
